(19) United States
(12) Patent Application Publication
(10) Pub. No.: US 2025/0298266 A1
(43) Pub. Date: Sep. 25, 2025

(54) OPTICAL ELEMENT, SMART GLASSES, OPTICAL COMMUNICATION SYSTEM, COMPUTER, AND METHOD FOR MANUFACTURING OPTICAL ELEMENT

(71) Applicant: TDK Corporation, Tokyo (JP)

(72) Inventors: Hideaki Fukuzawa, Tokyo (JP); Takashi Kikukawa, Tokyo (JP)

(73) Assignee: TDK Corporation, Tokyo (JP)

(21) Appl. No.: 19/080,600

(22) Filed: Mar. 14, 2025

(30) Foreign Application Priority Data
Mar. 19, 2024 (JP) 2024-043875

(51) Int. Cl. G02F 1/035; G02F 1/21; G02F 1/225

(52) U.S. Cl. CPC G02F 1/035; G02F 1/212; G02F 1/225; G02F 2202/20

(57) ABSTRACT

An object is to provide an optical element in which an optical waveguide including lithium niobate and a silicon substrate are integrated. An optical element is an optical element including a sapphire substrate having a first optical waveguide, and a silicon substrate. The first optical waveguide is constituted of a lithium niobate film provided on one surface of the sapphire substrate. The first optical waveguide is disposed in a manner of being sandwiched between the silicon substrate and the sapphire substrate.

### CROSS-REFERENCE TO RELATED APPLICATION

Priority is claimed on Japanese Patent Application No. 2024-043875, filed Mar. 19, 2024, the content of which is incorporated herein by reference.

### BACKGROUND OF THE INVENTION

### Field of the Invention

The present invention relates to an optical element, smart glasses, an optical communication system, a computer, and a method for manufacturing an optical element.

### Description of Related Art

With the spread of the Internet, communication traffic has increased dramatically, and in recent years, optical communication systems have been required to be high-speed and have large-capacity data processing capabilities.

In such optical communication systems, laser diodes and photodiodes are connected using optical waveguides. As a representative example of an optical waveguide, Patent Document 1 discloses an optical waveguide produced using a c-axis oriented LiNbO₃ thin film produced by sputtering on a sapphire substrate.

### PATENT DOCUMENT

[Patent Document 1] Japanese Unexamined Patent Application, First Publication No. 2022-131936

### SUMMARY OF THE INVENTION

However, regarding optical waveguides used in optical communication systems, some optical waveguides are provided on a substrate other than a sapphire substrate. When an optical communication system is realized, there is a need to connect optical waveguides to each other, and there is a need to connect optical waveguides (LN waveguides) of a lithium niobate film on a sapphire substrate and optical waveguides included in a different substrate. In this case, generally, the LN optical waveguides in an element form and the sapphire substrate are connected by arranging them next to optical waveguides in an element from provided on the different substrate. However, since chips each having two optical waveguides provided within substantially the same plane are mounted side by side, increase in size of the chips constituted of a plurality of optical waveguides is unavoidable.

In addition, in order to control an electro-optical element represented by an LN optical modulator including a lithium niobate film, there is a need to electrically connect chips having an electric circuit and LN optical waveguides on a sapphire substrate. However, in this case as well, there is a need to mount the chips having an electric circuit and the LN optical waveguides in a chip shape side by side within substantially the same plane, and increase in size of the chips in their entirety including the electric circuit and the LN optical waveguides is unavoidable.

The present disclosure has been made in consideration of the foregoing circumstances, and an object thereof is to provide an optical element avoiding increase in chip size and including an LN optical waveguide provided on a sapphire substrate and a substrate different from the sapphire substrate, smart glasses using the optical element, an optical communication system, a computer, and a method for manufacturing the optical element.

In order to resolve the foregoing problems, the present disclosure provides the following means.

An optical element according to an aspect of the present disclosure is an optical element including a sapphire substrate having a first optical waveguide, and a silicon substrate. The first optical waveguide is constituted of a lithium niobate film provided on one surface of the sapphire substrate. The first optical waveguide is disposed in a manner of being sandwiched between the silicon substrate and the sapphire substrate.

An optical communication system according to another aspect of the present disclosure uses the optical element according to the present disclosure.

Smart glasses according to another aspect of the present disclosure use the optical element according to the present disclosure.

A computer according to another aspect of the present disclosure includes PICs including the optical element according to the present disclosure, optical wirings, a plurality of GPUs, and a CPU. The PIC is included in the GPUs and the CPU, and the plurality of GPUs are connected to each other or the GPUs and the CPU are connected to each other via the PICs and the optical wirings.

A method for manufacturing an optical element according to another aspect of the present disclosure is a method for manufacturing an optical element constituted of a sapphire substrate and a substrate different from the sapphire substrate. The method has a first substrate patterning step of producing a first pattern by forming the first optical waveguide on one surface of the sapphire substrate, a second substrate patterning step of producing a second pattern on one surface of the substrate different from the sapphire substrate by patterning the substrate different from the sapphire substrate, a wafer bonding step of bonding one surface of the sapphire substrate having the first pattern formed in the first substrate patterning step and the one surface of the silicon substrate having the second pattern formed in the second substrate patterning step, and a dicing step of dicing the sapphire substrate and the substrate different from the sapphire substrate integrated in the wafer bonding step.

According to the optical element of the present disclosure, it is possible to provide an optical element avoiding increase in chip size and including an LN optical waveguide provided on a sapphire substrate and a substrate different from the sapphire substrate.

### BRIEF DESCRIPTION OF THE DRAWINGS

FIG. 1 is a perspective view of an optical element according to a first embodiment.

FIG. 2 is a cross-sectional view of the optical element according to the first embodiment.

FIG. 3 is another cross-sectional view of the optical element according to the first embodiment.

FIG. 4 is a perspective view of an optical element according to a second embodiment.

FIG. 5 is a cross-sectional view of the optical element according to the second embodiment.

FIG. 6 is another cross-sectional view of the optical element according to the second embodiment.

FIG. 7 is a perspective view of an optical element according to a third embodiment.

FIG. 8 is a cross-sectional view of the optical element according to the third embodiment.

FIG. 9 is a flowchart of a manufacturing method of the present embodiment.

FIG. 10 is a detailed view of a method for manufacturing an optical element of the first embodiment.

FIG. 11 is another detailed view of the method for manufacturing an optical element of the first embodiment.

FIG. 12 is another detailed view of the method for manufacturing an optical element of the first embodiment.

FIG. 13 is a detailed view of the method for manufacturing an optical element of the second embodiment.

FIG. 14 is a detailed view of the method for manufacturing an optical element of the third embodiment.

FIG. 15 is a view of an optical element with a light source, in which a laser diode is attached to the optical element of the present embodiment.

FIG. 16 is a view of an optical communication system using the optical element of the present embodiment.

FIG. 17 is a view of smart glasses using the optical element of the present embodiment.

FIG. 18 is a view of a computer using the optical element of the present embodiment.

### DETAILED DESCRIPTION OF THE INVENTION

Hereinafter, the present embodiment will be described in detail suitably with reference to the drawings. In the drawings used in the following description, in order to make characteristics easy to understand, characteristic portions may be shown in an enlarged manner for the sake of convenience, and dimensional ratios or the like of each constituent element may differ from actual values thereof. Materials, dimensions, and the like shown in the following description are merely exemplary examples. The present invention is not limited thereto and can be suitably changed and performed within a range in which the effects of the present invention are exhibited.

First, directions will be defined. One direction on a surface of a wafer will be referred to as an X direction. A normal direction on the surface of the wafer will be referred to as a Y direction, and a direction perpendicular to the X direction within the surface of the wafer will be referred to as a Z direction. Here, it is assumed that a thin film is laminated in the Y direction and light is wave-guided in the Z direction.

### First Embodiment

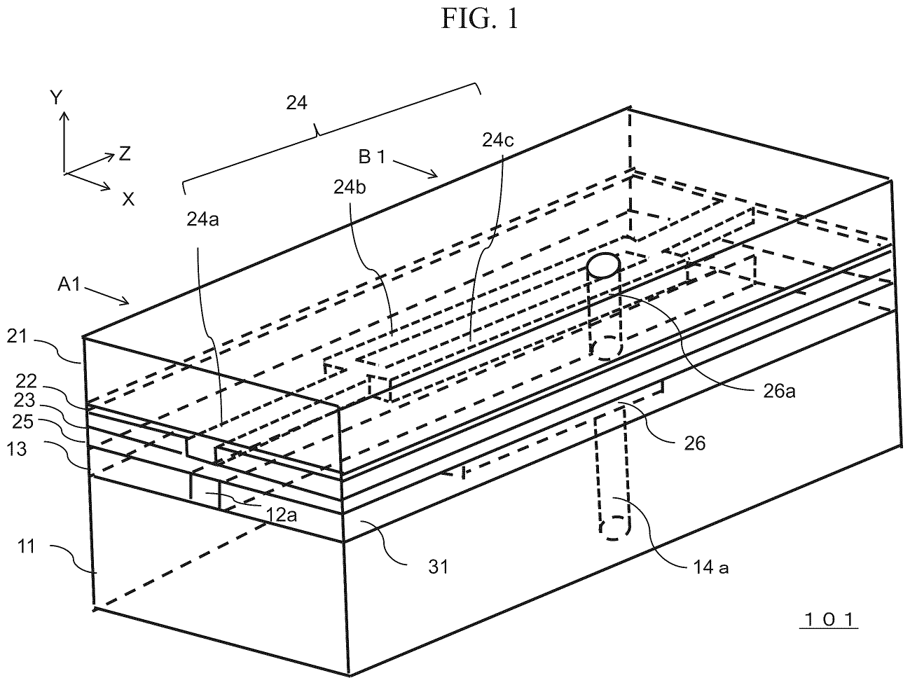

FIG. 1 is a perspective view of an optical element 101 according to a first embodiment. The optical element 101 is produced by adhering wafers having a patterned silicon substrate 11 (substrate different from a sapphire substrate) and a patterned sapphire substrate 21 to each other and performing dicing.

The constitution of the optical element 101 on the silicon substrate side will be described. The silicon substrate side is constituted of the silicon substrate 11, a core layer 12a patterned on one surface of the silicon substrate, a cladding layer 13 in which the patterned core layer 12a is embedded (Si cladding layer), and a through electrode 14a on the silicon substrate side (Si through electrode). Here, the core layer 12a forms an optical waveguide (Si optical waveguide) together with the silicon substrate 11 and the Si cladding layer 13.

The material of the core layer 12a is a silicon film (Si film) such as polysilicon or a SiNx (silicon nitride) film. The Si cladding layer is a SiO₂ (silicon oxide) film. As long as the refractive index of the core layer 12a is designed to be larger than the refractive indices of the silicon substrate 11 and the cladding layer 13, the form of the Si optical waveguide is not limited to an embedded-type optical waveguide, and it is possible to suitably employ various types of waveguides, such as a type in which a projecting shape is made on a silicon substrate and light is trapped by surrounding air, and a type in which a Si film or a SiNx film having a strip shape is disposed on an upper surface of a Si cladding layer and light is trapped in a space made by surrounding air.

The Si through electrode 14a is an electrode penetrating a silicon substrate and is formed using a so-called through-silicon via (TSV) mounting technology.

Next, the constitution of the optical element 101 on the sapphire substrate side will be described. It is constituted of the sapphire substrate 21, an epitaxial film 22 (LN thin film) of c-axis oriented lithium niobate provided on one surface thereof, LN ridge portions 24a, 24b, and 24c obtained by processing the LN thin film through etching or the like, a cladding layer 23 (LN cladding layer) covering side surfaces of the LN ridge portion, a buffer layer 25 (LN buffer layer) provided on a surface on a side opposite to the sapphire substrate side of the LN ridge portion, and an electrode 26 on the LN side (LN electrode).

The LN thin film 22 is an epitaxial film epitaxially grown on the sapphire substrate 21. The epitaxial film is a single-crystal film in which the crystal orientation is aligned by a base substrate. The epitaxial film is a film which has a single-crystal orientation in the Y direction and a direction within an XZ plane and in which crystal is oriented in a manner of being aligned in all of an X axis direction, a Y axis direction, and a Z axis direction. Whether or not the film formed on the sapphire substrate 21 is an epitaxial film can be verified, for example, by checking the peak intensity and the pole at the orientation position in 2θ-θX ray diffraction.

The film thickness of the LN thin film 22 is 2 μm or smaller, for example. The film thickness of the lithium niobate film 22 is a film thickness of a part other than the LN ridge portion. If a lithium niobate film 40 has a large film thickness, there is concern that crystallinity may be degraded. In addition, the film thickness of the lithium niobate film 40 is approximately 1/10 or larger than the wavelength of light used, for example.

The LN cladding layer 23 covers and protects the side surfaces of the LN ridge portion and is made of SiO₂, Al₂O₃, MgF₂, La₂O₃, ZnO, HfO₂, MgO, Y₂O₃, CaF₂, In₂O₃, or a mixture of these.

The LN buffer layer 25 covers and protects a lower surface of the LN ridge portion and is made of SiO₂, Al₂O₃, MgF₂, La₂O₃, ZnO, HfO₂, MgO, Y₂O₃, CaF₂, In₂O₃, or a mixture of these.

The LN ridge portions 24a, 24b, and 24c form ridge-type optical waveguides (LN optical waveguides) together with the LN thin film 22, the LN cladding layer 23, and the LN buffer layer 25 around them. As long as the LN ridge portion is constituted to have a higher refractive index than its surroundings, it may be not only a type of being embedded in a cladding layer or an LN buffer layer but also a type in which air is disposed around an LN ridge portion to trap light and wave-guide the light.

The LN ridge portion 24a is connected to the LN ridge portions 24b and 24c via branching portions, and the LN ridge portions 24a, 24b, and 24c constitute 24 Mach-Zehnder interference-type optical waveguides (MZI optical waveguides) in total, which are LN optical waveguides. The LN electrode 26 applies an electric field to each ray of branched wave-guided light propagating through the LN ridge portion 24b and the LN ridge portion 24c. Since lithium niobate has an electro-optic effect, the phase of wave-guided light changes in response to the applied electric field, and if branched wave-guided light is multiplexed, modulated light whose phase is controlled by the electric field can be obtained. That is, an optical element having a function of an LN optical modulator is integrated on the sapphire substrate 21 by the MZI optical waveguides 24 and the LN electrode 26.

A part of the LN electrode 26 includes a through electrode 26a (LN through electrode) formed by embedding metal into a through hole provided in the sapphire substrate.

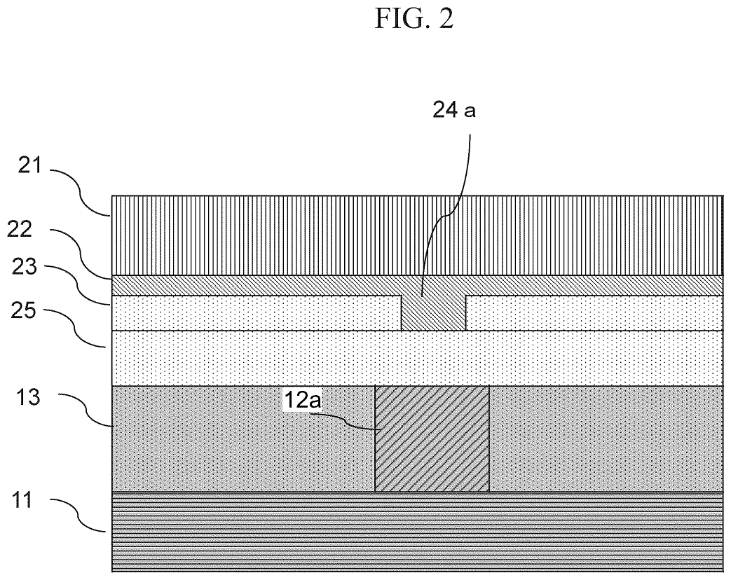

FIG. 2 is a cross-sectional view of an XY plane viewed in the Z direction that is a proceeding direction of light from the point of A1 in FIG. 1. A Si optical waveguide 12a is formed from a core layer and is disposed in a manner of being surrounded by the silicon substrate 11 and the cladding layer 13. When viewed in the Y direction of lamination, the LN buffer layer 25 of LN is provided on an optical waveguide 12a on the silicon side, and the LN ridge portion 24a is provided on the LN buffer layer. The LN thin film 22 is provided on the LN ridge portion 24a, and the sapphire substrate is provided thereon.

The light wave-guided through the Si optical waveguide 12a and the light wave-guided through the MZI optical waveguides 24 can be optically coupled to each other by selecting the film thickness and the material of the Si cladding layer 13, the LN buffer layer 25, and the like. That is, the Si optical waveguide and the MZI optical waveguides can be optically connected. Alternatively, each ray of light can independently propagate.

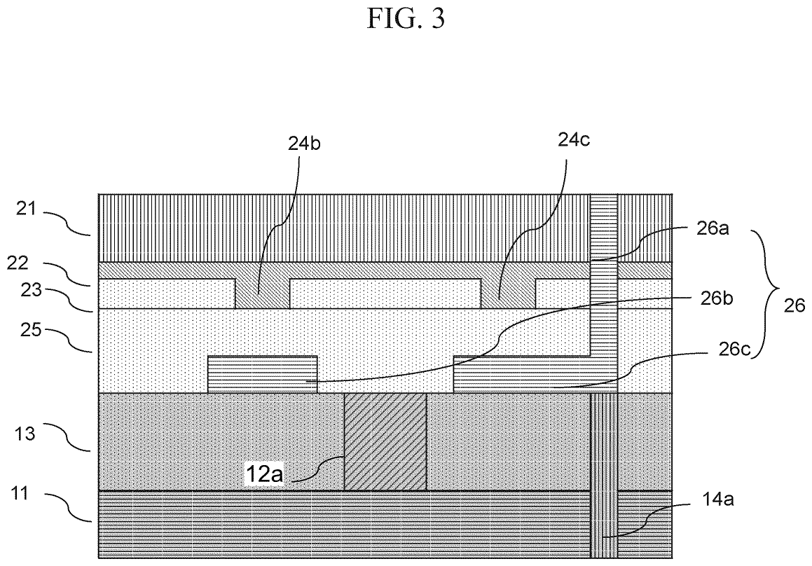

FIG. 3 is another cross-sectional view of an XY plane viewed in the Z direction that is the proceeding direction of light from the point of B1 in FIG. 1. The optical waveguide 12a on the silicon side is formed from a core layer and is disposed in a manner of being surrounded by the silicon substrate 11 and the cladding layer 13. An electrode 26b on the LN side is disposed on an electrode 14b on the silicon side. In addition, an electrode 26c on the LN side is disposed on an electrode 14c on the silicon substrate side. The LN buffer layer 25 is disposed on the electrodes 26a and 26b on the LN side, and the LN ridge portions 24b and 24c are disposed on the LN buffer layer. The cladding layer 23 is provided around the LN ridge portions 24b and 24c. The LN thin film 22 is provided on the LN ridge portion, and the sapphire substrate 21 is provided on the LN thin film 22.

The LN through electrode 26a is connected to the upper surface of the sapphire substrate through the through hole. In addition, by applying a voltage while having the electrode 26b on the LN side as a signal electrode (LN signal electrode) and having the electrode 26c on the LN side as a grounding electrode (LN grounding electrode), electric fields can be applied to light wave-guided through the LN ridge portion 24b and the LN ridge portion 24c in directions opposite to each other. Since the LN thin film is a c-axis oriented sputtered film, TM-mode light whose polarization direction is parallel to the c axis is wave-guided. Since electric fields are applied to the wave-guided TM-mode light in directions opposite to each other, the signs of the amounts of phase change of light wave-guided through the LN ridge portion 24b (first arm) serving as a first arm and the LN ridge portion 24c (second arm) serving as a second arm become opposite so that on-off operation of light multiplexed with respect to the on-off operation of the electric field can be performed and they can operate as optical modulators.

The silicon substrate 11 and the sapphire substrate 21 may be bonded by a method of surface activated bonding or atomic diffusion bonding or may be bonded using a resin. As long as they can be bonded, any method can be adopted. Depending on the selected method, an altered layer or a resin layer is added to the bonded surface, but illustration thereof is omitted.

Thus far, the optical element 101 according to the first embodiment has been described. Regarding the optical element 101, the optical element 101 has the LN optical waveguides serving as first optical waveguides and are disposed in a manner of being sandwiched between the silicon substrate 11 and the sapphire substrate 21, and the optical element 101 can realize an optical element in which silicon photonics and an LN thin film are fused by realizing a packaging step at wafer level with favorable mass production.

### Second Embodiment

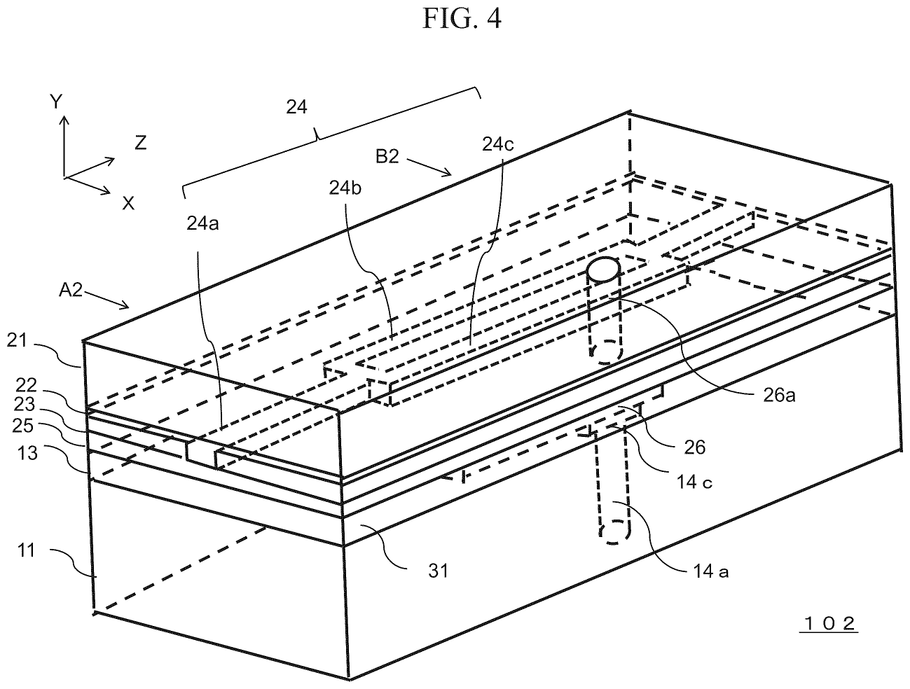

Next, an optical element 102 according to a second embodiment will be described. FIG. 4 is a perspective view of the optical element 102 according to the second embodiment. Description for parts similar to those of the first embodiment will be omitted.

The constitution of the optical element 102 on the silicon substrate side will be described. The silicon substrate side is constituted to include the silicon substrate 11, the cladding layer 13 (Si cladding layer) provided on the silicon substrate, the through electrode 14a on the silicon substrate side (Si through electrode), and the grounding electrode 14c (Si grounding electrode).

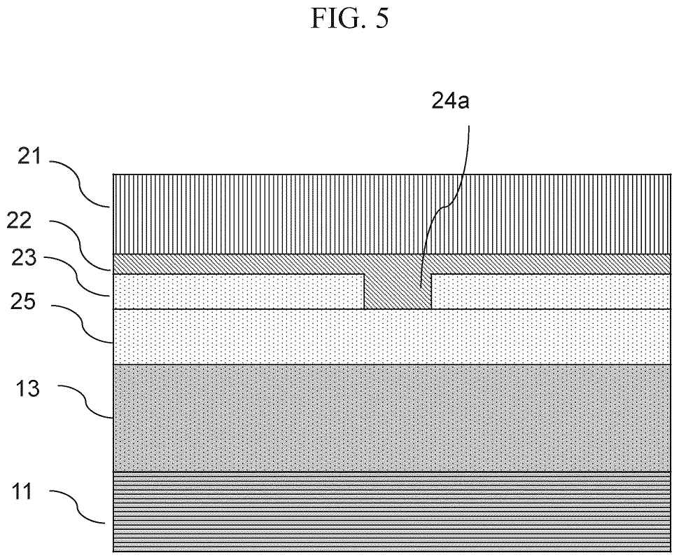

FIG. 5 is a cross-sectional view of an XY plane viewed in the Z direction that is the proceeding direction of light from the point of A2 in FIG. 4. The Si cladding layer 13 is provided on the silicon substrate 11. When viewed in the Y direction of lamination, the LN buffer layer 25 is provided on the Si cladding layer, and the LN ridge portion 24a is provided on the LN buffer layer. The LN thin film 22 is provided on the LN ridge portion 24a, and the sapphire substrate is provided thereon.

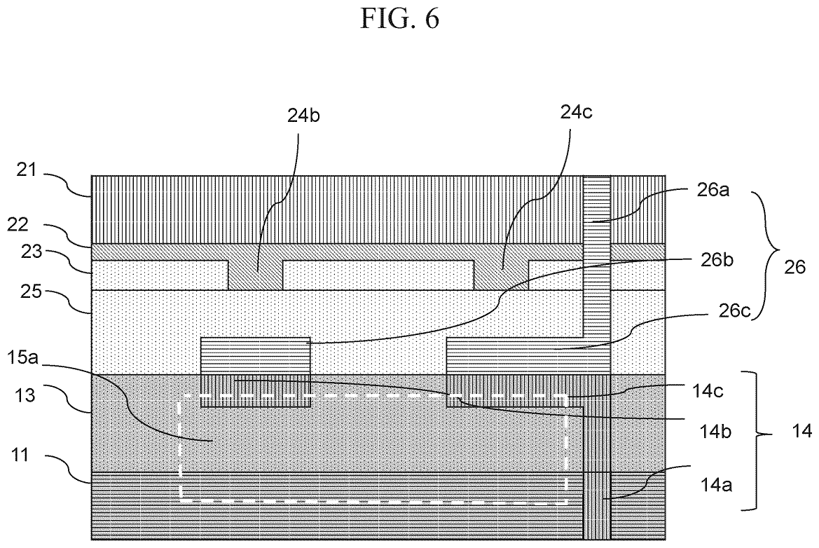

FIG. 6 is another cross-sectional view of an XY plane viewed in the Z direction that is the proceeding direction of light from the point of B2 in FIG. 4. The Si cladding layer 13 is disposed on the silicon substrate 11. Each of the signal electrode 14b on the silicon side (Si signal electrode) and the grounding electrode 14c on the silicon side (Si grounding electrode) is provided on a surface of the Si cladding layer 13. The electrode 26b on the LN side is disposed on the Si signal electrode 14b, and the LN grounding electrode 26c is disposed on the Si grounding electrode 14c. The LN buffer layer 25 is disposed on the LN signal electrode 26b and the LN grounding electrode 26c, and the LN ridge portions 24b and 24c are disposed on the LN buffer layer. The cladding layer 23 is provided around the LN ridge portions 24b and 24c. The LN thin film 22 is provided on the LN ridge portion, and the sapphire substrate 21 is provided on the LN thin film 22.

Here, the silicon substrate 11, the Si cladding layer 13, the Si signal electrode 14b, and the Si grounding electrode 14c constitute a CMOS circuit 15a (electric circuit) including a transistor, and the Si through electrode 14a serves as a grounding electrode connecting the Si grounding electrode 14c to the outside via the through hole of the silicon substrate.

Although it is not illustrated, the impurity concentration in ion implantation or the like on a surface of the Si substrate may be adjusted, and a wiring layer constituting a CMOS circuit may be formed inside the Si cladding layer.

The silicon substrate 11 and the sapphire substrate 21 may be bonded by the method of surface activated bonding or atomic diffusion bonding or may be bonded using a resin. As long as they can be bonded, any method can be adopted. By performing wafer bonding, the Si signal electrode 14b is electrically connected to the LN signal electrode 26b and the Si grounding electrode is electrically connected to the LN grounding electrode 26c, respectively.

For example, the CMOS circuit 15a serves as a driver circuit of an LN modulator and a high-frequency electric signal propagates to the first arm 24b via the Si signal electrode 14b serving as the signal electrode of the CMOS circuit, and thus high-speed modulated wave-guided light can be obtained.

Thus far, the optical element 102 according to the second embodiment has been described. The optical element 102 can be actively operated by applying an electric field to the LN optical waveguides serving as the first optical waveguides.

### Third Embodiment

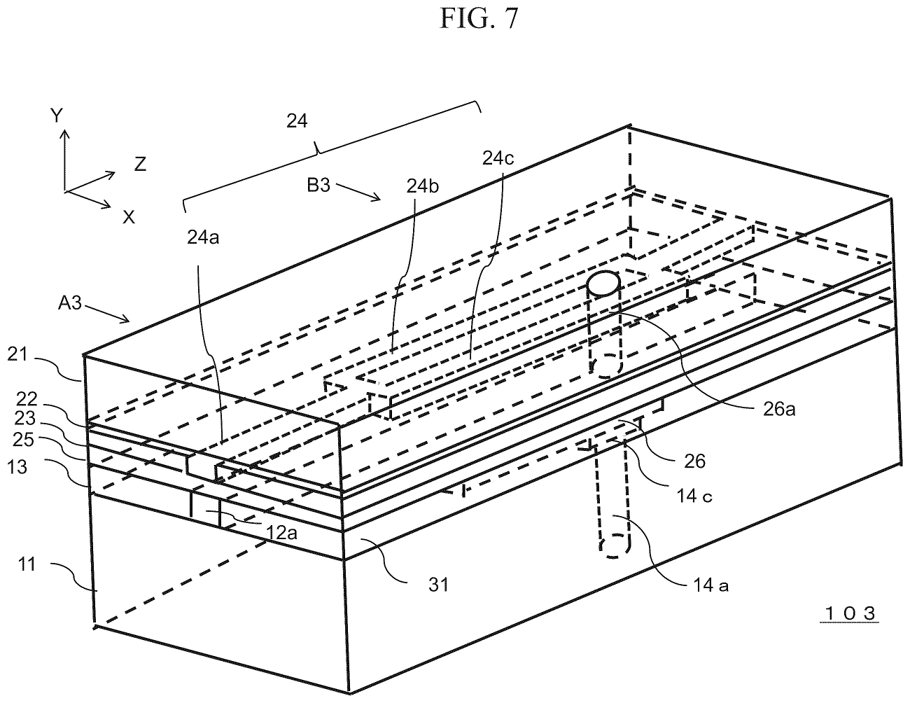

FIG. 7 is a perspective view of an optical element 103 according to a third embodiment. Description for parts similar to those of the first embodiment and the second embodiment will be omitted.

The optical element 103 is constituted to have the Si optical waveguide 12a of the first embodiment and the CMOS circuit 15a of the second embodiment together on the silicon substrate side. A cross-sectional view of an XY plane viewed in the Z direction that is the proceeding direction of light from the point A3 is similar to that of the first embodiment.

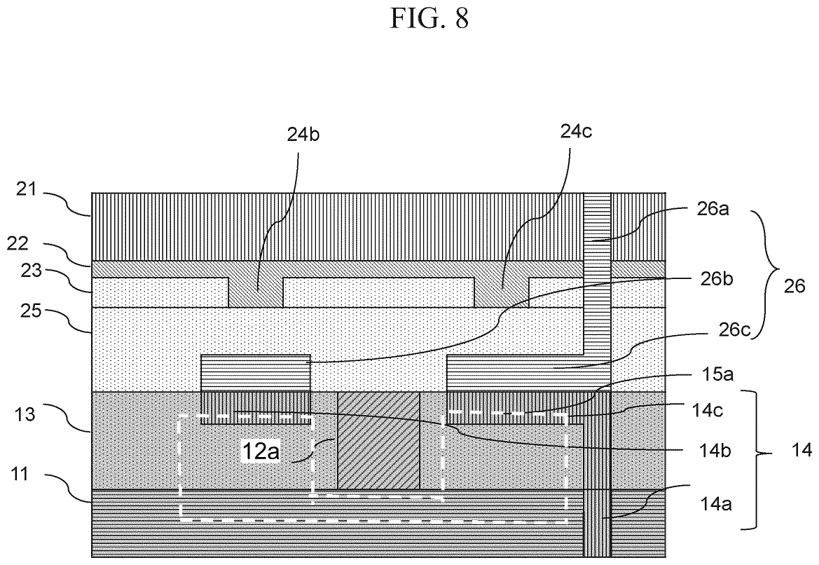

FIG. 8 is a cross-sectional view of an XY plane viewed in the Z direction that is the proceeding direction of light from the point of B3 in FIG. 8. The Si optical waveguide 12a and the CMOS circuit 15a including the transistor are provided in the Si cladding layer 13.

Here, an example in which the optical waveguide 12a on the silicon side and the CMOS circuit 15a are disposed within the same XY plane has been described, but a wiring may be routed within the XZ plane and connected to the electrodes 26a and 26b on the LN side. The optical waveguide 12a on the silicon side and the CMOS circuit 15a may be disposed at positions where optical characteristics of the optical waveguide 12a on the silicon side and electrical characteristics of the CMOS circuit 15a do not affect each other.

Here, an example in which the optical waveguide 12a on the silicon side and the CMOS circuit 15a are disposed within the same XY plane has been described, but a wiring may be routed within the XZ plane and connected to the electrodes 26a and 26b on the LN side. The optical waveguide 12a on the silicon side and the CMOS circuit 15a may be disposed at positions where optical characteristics of the optical waveguide 12a on the silicon side and electrical characteristics of the CMOS circuit 15a do not affect each other.

Thus far, the optical element 103 according to the third embodiment has been described. The optical element 103 has the LN optical waveguides serving as the first optical waveguides and the Si optical waveguide serving as a second optical waveguide together, and thus it can be actively operated by applying an electric field. Moreover, the relationship between the light wave-guided through the LN optical waveguides and the light wave-guided through the Si optical waveguide can be utilized.

### Embodiment of Method for Manufacturing Optical Element

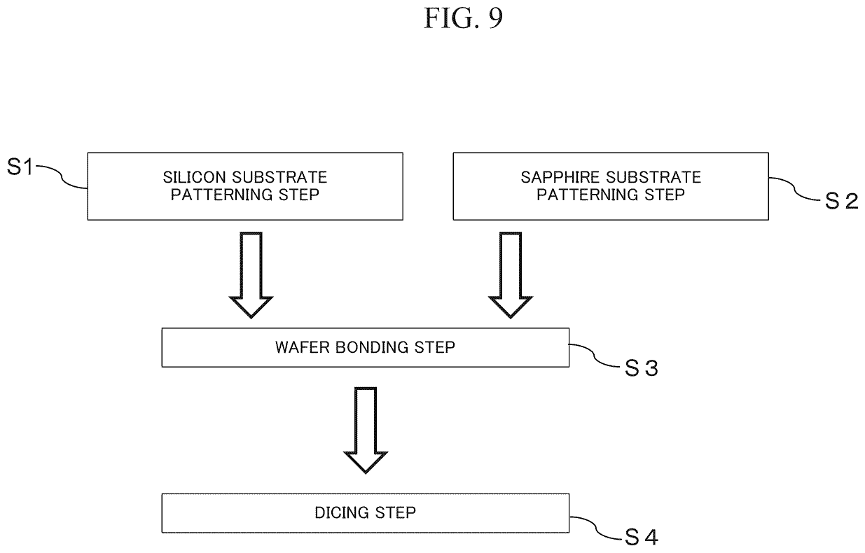

Next, an embodiment of the method for manufacturing an optical element will be described. FIG. 9 is a flowchart of the method for manufacturing the optical element 101. The method is constituted of a silicon substrate patterning step (first substrate patterning step) S1, a sapphire substrate patterning step (second substrate patterning step) S2, a wafer bonding step S3, and a dicing step S4. The silicon substrate patterning step S1 and the sapphire substrate patterning step S2 may be performed in any order. Wafer bonding of the silicon substrate and the sapphire substrate patterned in the wafer bonding step S3 is performed. Thereafter, the wafer-bonded substrate is diced in the dicing step, and the optical element is cut out.

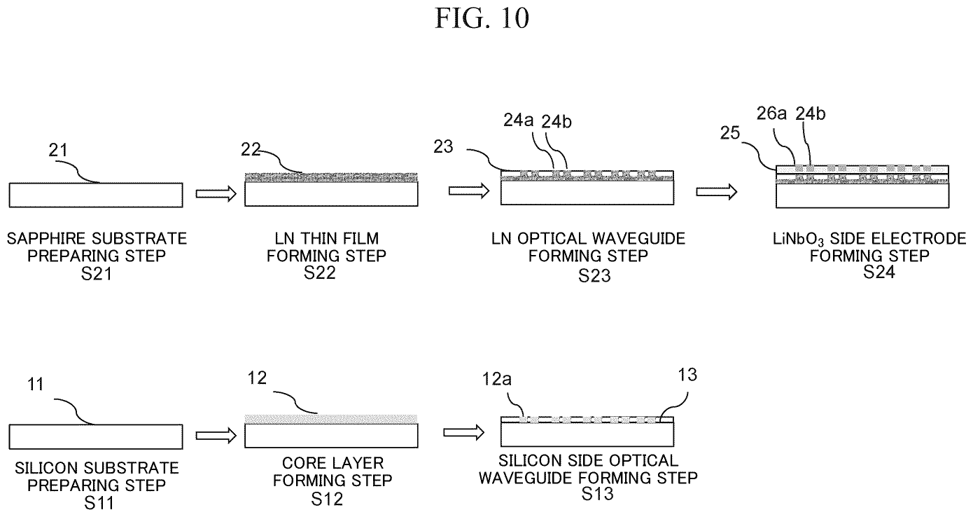

FIGS. 10 to 12 describe in detail the method for manufacturing the optical element 101 having an optical waveguide on the silicon substrate side and having an LN optical modulator on the sapphire substrate side. FIG. 10 shows the silicon substrate patterning step S1 and the sapphire substrate patterning step S2.

In the silicon substrate patterning step S1, first, the silicon substrate 11 that is a substrate different from the sapphire substrate is prepared in a silicon substrate preparing step S11. Thereafter, as a core layer forming step S12, a polysilicon film or a silicon nitride (SiNx) film is deposited. Thereafter, in a silicon side optical waveguide forming step S13, a waveguide pattern is formed by photolithography and etching such that an optical waveguide is formed. Thereafter, the waveguide pattern is formed, and then a silicon oxide (SiO₂) is deposited. The optical waveguide (Si optical waveguide) having the embedded core layer 12a as a core is formed, and a patterned silicon substrate is obtained.

In the sapphire substrate patterning step S2, first, the sapphire substrate 21 is prepared in a sapphire substrate preparing step S21. Thereafter, as an LN film layer forming step S22, a c-axis oriented LiNbO₃ film is deposited by sputtering. Thereafter, in an LN optical waveguide forming step S23, the pattern of the optical waveguide is patterned on the LN thin film by photolithography, and the LN ridge portions 24a, 24b, and 24c are formed by milling or etching. Thereafter, the cladding layer 23 (LN cladding layer) that is an insulation film is deposited around the LN ridge portion.

Thereafter, in an LN electrode forming step S24, an LN buffer layer is deposited, and an electrode pattern serving as an LN electrode is produced by photolithography, electrode vapor deposition, lifting-off, etching, or the like. In this manner, a patterned sapphire substrate is obtained.

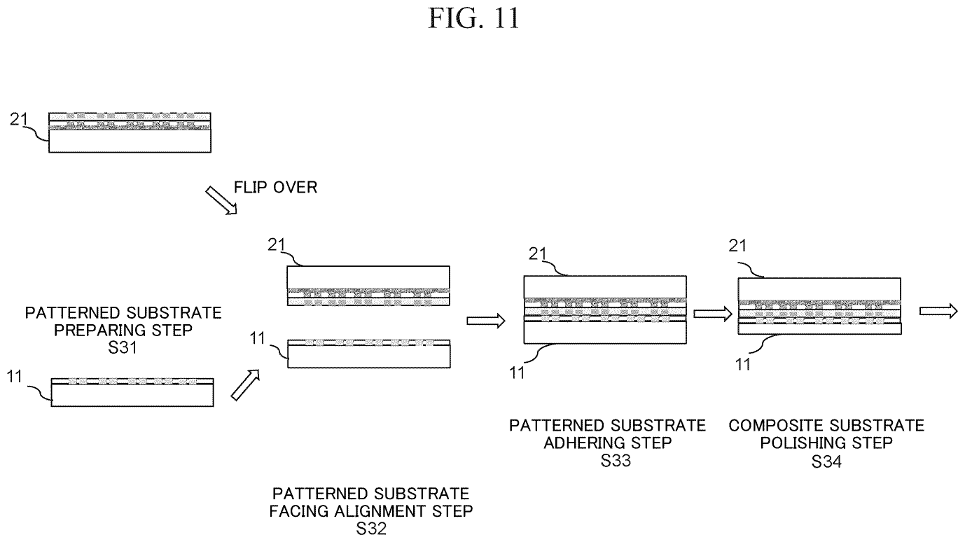

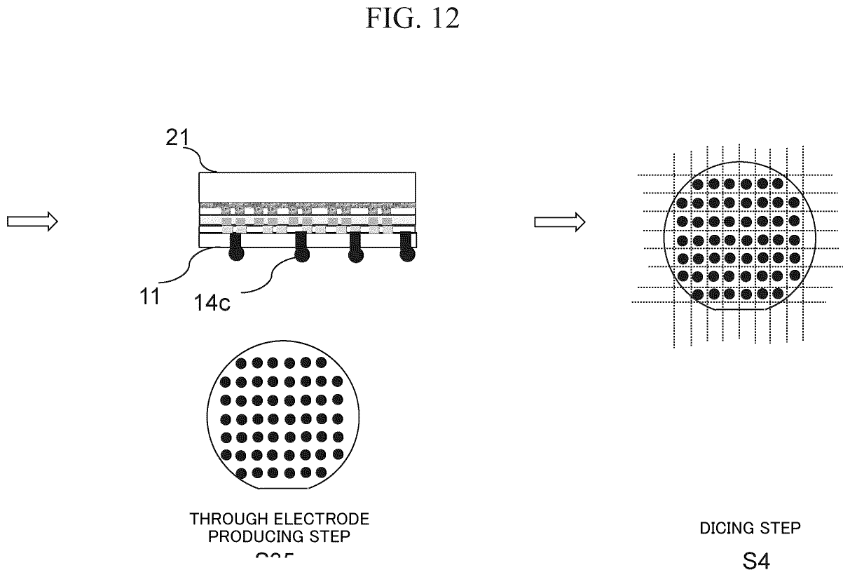

In FIG. 11, details of a wafer bonding step 3 will be described. In a patterned substrate preparing step S31, the patterned silicon substrate produced in the silicon substrate patterning step and the patterned sapphire substrate produced in the sapphire substrate patterning step are prepared. Thereafter, in a patterned substrate facing alignment step 32, alignment is performed by causing the patterned surfaces of the silicon substrate 11 and the sapphire substrate 21 to face each other. Thereafter, in a patterned substrate adhering step S33, the silicon substrate 11 and the sapphire substrate 21 are adhered. The wafer bonding method at this time includes a method of surface activated bonding or atomic diffusion bonding, and a bonding method using a resin. Thereafter, in a composite substrate polishing step, an integrated composite substrate is polished from the lower surface of the silicon substrate and the upper surface of the sapphire substrate. As shown in FIG. 12, after the composite substrate polishing step, in a through electrode producing step S35, a through hole penetrating the lower surface of the silicon substrate is produced, and a through electrode is formed by embedding a metal into the produced through hole. Thereafter, in the dicing step S4, the optical element 101 can be obtained by cutting out the composite substrate into pieces of element size by dicing.

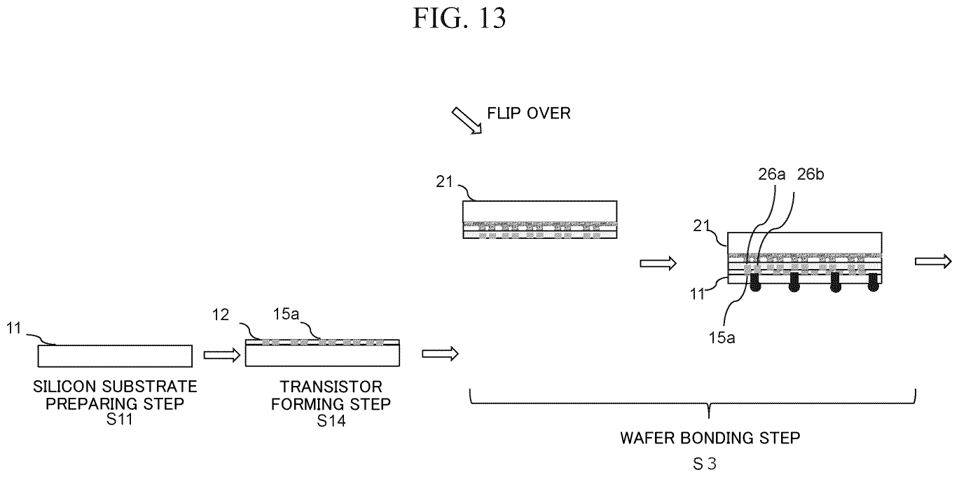

In FIG. 13, the method for manufacturing the optical element 102 having a CMOS circuit including a transistor on the silicon substrate and having a LiNbO₃ optical modulator on the sapphire substrate side will be described in detail. Description of steps which have already been described will be omitted. In the silicon substrate patterning step (first substrate patterning step), after the silicon substrate preparing step S11, a transistor forming step S14 is performed. In the transistor forming step, the silicon substrate 11 is subjected to ion implantation, thermal diffusion, or the like, and the impurity concentration in the vicinity of the surface of the Si substrate is adjusted. A cladding layer 12 that is an insulation layer and an electrode serving as a wiring layer inside the cladding layer are produced, and an electrode on the silicon side connected the electrode on the LN side is formed, thereby forming the CMOS circuit 15a including the transistor. Thereafter, the patterned silicon substrate having a transistor and the patterned sapphire substrate are bonded in the wafer bonding step 3. Thereafter, in the dicing step S4, the optical element 102 can be obtained by cutting out the composite substrate into pieces of element size by dicing.

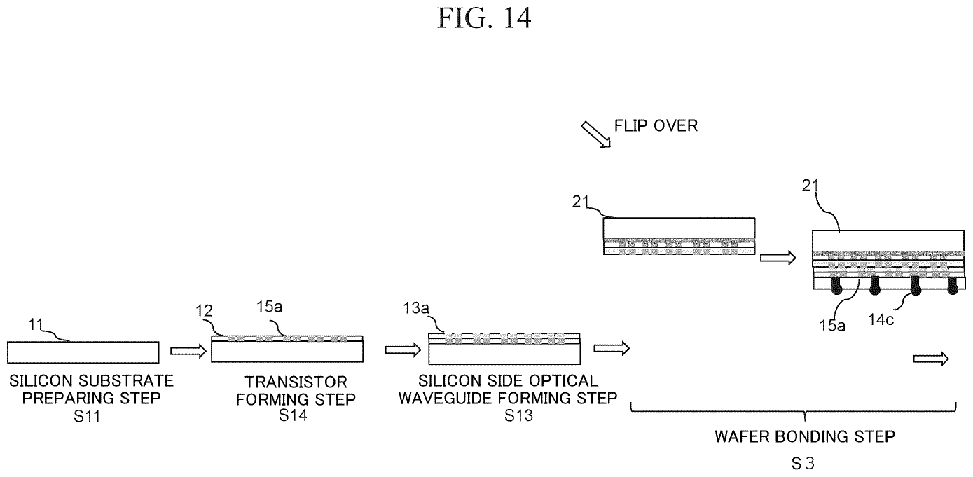

In FIG. 14, the method for manufacturing the optical element 103 having a transistor and an optical waveguide on the silicon substrate and an LN optical modulator on the sapphire substrate side will be described in detail. Description of steps which have already been described will be omitted. In the silicon substrate patterning step, after the silicon substrate preparing step S11, the transistor forming step S14 is performed, and the CMOS circuit 15a is formed. Thereafter, the silicon side optical waveguide forming step S13 is performed. In the silicon side optical waveguide forming step, the core layer 12a such as a silicon film or a SiNx film is formed, a waveguide pattern is formed by photolithography or etching, and a cladding layer is embedded around the waveguide pattern. For the cladding layer, a material such as Si (2 having a lower refractive index than the core layer can be suitably selected. Thereafter, in the wafer bonding step 3, the patterned silicon substrate and the patterned sapphire substrate are adhered. Thereafter, in the dicing step S4, the optical element 102 can be obtained by cutting out the composite substrate into pieces of element size by dicing.

In the foregoing examples, the method for manufacturing an optical element serving as a composite substrate by forming lithium niobate on a sapphire substrate has been described. It is also conceivable to manufacture an optical element by forming lithium niobate on a silicon substrate instead of a sapphire substrate. In this case, in order to form a lithium niobate element on the silicon substrate, there is a need to attach bulk lithium niobate to the silicon substrate and then make an element using it.

However, there is a need for bulk lithium niobate to be formed to have a size equivalent to that of a silicon substrate, and it is not possible to form a lithium niobate film having a general size of 12 inches on a silicon substrate so that fusion of a lithium niobate element and an optical waveguide formed on a silicon substrate is limited to approximately 6 inches. Therefore, optical elements can be obtained by processing wafers equal to or larger than 6 inches.

### Embodiment of Optical Element With Laser Diode

Subsequently, regarding another application example, an optical element 201 including a laser diode (optical element with a laser diode) will be described. An embodiment of an optical element with a laser diode in which a laser diode is connected to the Si optical waveguide 12a of the optical element 103 or the input portion 24a of the LN optical waveguide will be described.

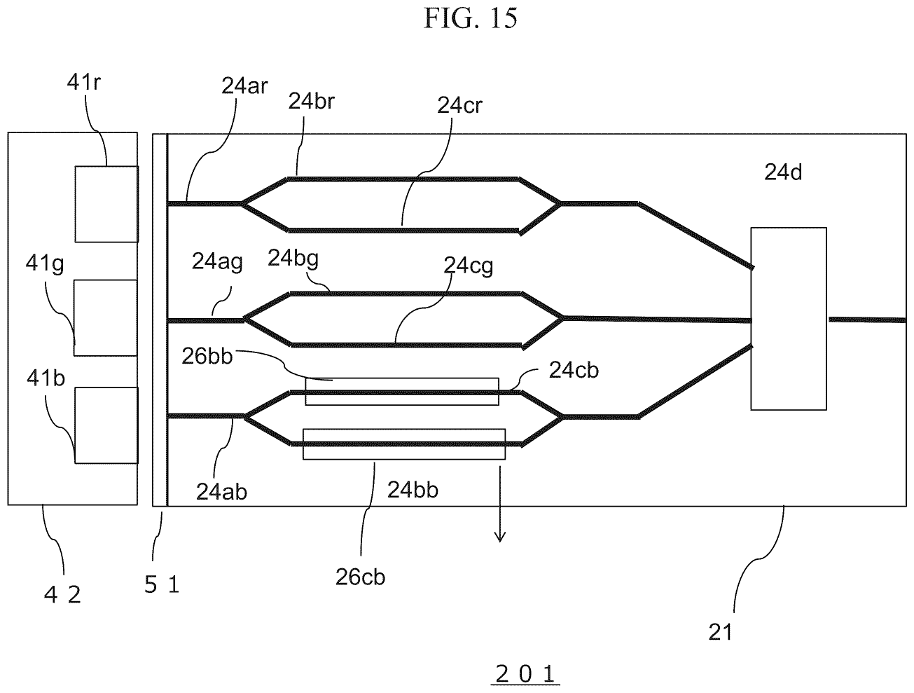

FIG. 15 is a view of an XZ plane of an optical element with a laser diode, in which a laser diode is attached to the optical element 103, and in the optical element 103, the LN optical waveguide on the sapphire substrate side is viewed in the provided XZ plane. Regarding the sapphire substrate, three sets of MZI optical waveguides wave-guiding light having visible light wavelengths of 400 nm to 700 nm, a multiplexer multiplexing the MZI optical waveguides into one LN optical waveguide, three sets of LN signal electrodes, and an LN grounding electrode are provided on the sapphire substrate. Output portions of the MZI optical waveguides are multiplexed by the multiplexer.

LN optical waveguides 24ar, 24br, and 24cr constitute MZI optical waveguides corresponding to red, LN optical waveguides 24ag, 24bg, and 24cg constitute MZI optical waveguides corresponding to green, and LN optical waveguides 24ab, 24bb, and 24cb constitute MZI optical waveguides corresponding to blue. Three sets of the LN signal electrode 26b and the LN grounding electrode 26c are provided on the sapphire substrate. Here, an LN signal electrode 26bb and an LN grounding electrode 26cb corresponding to blue are illustrated. Output portions of the respective MZI optical waveguides are multiplexed by a multiplexer 24d.

An optical semiconductor element 41r emitting red light, an optical semiconductor element 41g emitting green light, and an optical semiconductor element 41b emitting blue light are respectively connected to input portions of three sets of the MZI optical waveguides. Moreover, rays of light respectively having wavelengths of red, green, and blue are modulated by three sets of LN electrodes. In this manner, the size of the optical element with a laser diode can be reduced using the optical element 103. In addition, regarding the LN modulator, since an external modulator having extremely high insulation properties is controlled with a voltage, almost no current is required for intensity modulation and it operates with a minimum necessary current for emission of laser, which enables low power consumption.

In addition, each of the optical semiconductor elements is mounted on a subcarrier (base) 42, and the MZI optical waveguides are sandwiched between the sapphire substrate and the silicon substrate.

Various laser elements can be used as the optical semiconductor elements. For example, commercially available laser diodes (LDs) of red light, green light, blue light, and the like can be used. Light having a peak wavelength of 610 nm to 750 nm can be used as red light, light having a peak wavelength of 500 nm to 560 nm can be used as green light, and light having a peak wavelength of 435 nm to 480 nm can be used as blue light.

In the optical element with a laser diode, it is assumed that three optical semiconductor elements respectively serve as an LD 41b emitting blue light, an LD 41g emitting green light, and an LD 41r emitting red light. They are disposed with an interval therebetween in a direction substantially orthogonal to the emission direction of light emitted from each of the LDs.

The LDs are mounted on the subcarrier 42 as bare chips, and the subcarrier 42 can be constituted to be directly bonded to the composite substrate of the sapphire substrate and the silicon substrate with a metal layer therebetween. With this constitution, since spatial coupling or fiber coupling is not performed, further miniaturization can be achieved.

In the optical element 201 with a laser diode, an antireflection film 51 is provided between the LD and the light incidence surface of the light input portion 24a. For example, the antireflection film is formed integrally with the side surface of the sapphire substrate, the LD, and the light incidence surface of the light input portion 24a. However, the antireflection film may be formed on only the light incidence surface of the light input portion 24a of the LN optical waveguide.

The antireflection film 51 is a film for preventing reflection in the direction opposite to the direction of entry from the light incidence surface of the light input portion 24a and enhancing the transmittance rate of incident light. For example, the antireflection film is a multilayer film formed by alternately laminating a plurality of kinds of dielectrics with predetermined thicknesses corresponding to wavelengths of red light, green light, and blue light (incident light). Examples of the dielectrics described above include titanium dioxide (TiO₂), tantalum oxide (Ta₂O₅), silicon oxide (SiO₂), and aluminum oxide (Al₂O₃).

The emission surface of the LD and the light incidence surface of the LN light input portion 24a are disposed with a predetermined interval therebetween. The light incidence surface of the LN light input portion 24a faces the emission surface of the LD, and there is a gap between the LD emission surface and the light incidence surface of the LN optical waveguide in the Z direction. Since the optical element with a laser diode is exposed to the air, the gap is filled with air. Since the gaps are in a state of being filled with the same gas (air), it is easy to cause rays of light of colors respectively emitted from the LDs to be incident on incidence paths in a state of satisfying predetermined coupling efficiency. When the optical element with a laser is used in AR glasses and VR glasses, in consideration of the quantity of light and the like required for AR glasses and the VR glasses, the size of the gap (interval) in the Z direction is larger than 0 μm and is equal to or smaller than 5 μm, for example.

Hereinabove, regarding the optical element with a laser diode, and example in which laser diodes of visible light are connected to LN optical waveguides has been described, but they may be connected to the Si optical waveguide. In addition, if the LN optical waveguides or the Si optical waveguide is constituted such that near infrared light of 800 nm to 1600 nm propagates, laser diodes emitting near infrared light of 800 nm to 1600 nm may be connected.

In this manner, miniaturization of a visible light source device emitting visible light or a near infrared light source device emitting near infrared light can be realized by attaching laser diodes to the optical element according to the present disclosure.

### Embodiment of Optical Communication System

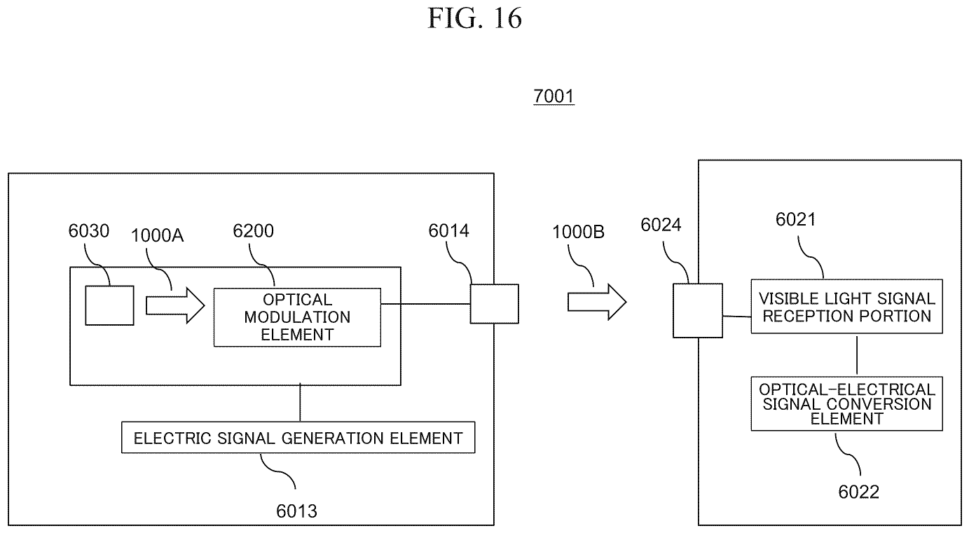

Next, regarding another application example, an embodiment of an optical communication system using the optical element according to the present disclosure will be described. An optical communication system 7001 shown in FIG. 16 includes a transmission device 6001 and a reception device 6002.

A light source unit 6001 includes a laser diode 6030 for an optical communication system, an optical modulation element 6200 for an optical communication system, an electric signal generation element 6013, and a signal emission port 6014. The laser diode 6030 for an optical communication system includes the optical element 201 with a laser diode.

A reception unit includes a signal incidence port 6024, a visible light signal reception portion 6021, and an optical-electrical signal conversion element 6022.

When visible light is used as light emitted from the light source unit 6001, it is possible to increase the generation speed of a visible light signal. With increasing processing speeds of computers and accompanying improvement in processing capability of information data, there is a demand for faster communication speeds in optical communication systems. However, in transmission devices generating a visible light signal by internal modulation, there is a limit to shortening the on/off switching time of the visible light sources, making it difficult to increase the generation speed of a visible light signal.

In addition, when the visible light sources are disposed in an array shape, since the size of the device increases, there is concern that it may be difficult to use them in small-sized information terminals such as smartphones, for example. In addition, when the visible light sources are disposed in an array shape, there is concern that data processing may become complicated. Moreover, using a plurality of light sources to enhance the processing capability of information data will make the constitution of the device complicated, resulting in extremely high costs. Thus, it is not realistic to apply such a constitution to transmission devices for consumer use.

When visible light is used in an optical communication system, the generation speed of a visible light signal increases, and miniaturization and low cost can be realized.

In the laser diode 6030 for an optical communication system, the red LD 41r, the green LD 41g, and the blue LD 41b are used, and they each emit visible light. The LDs are kept in a continuously ON state. The term “continuously” means that the LDs are kept in an ON state during the period in which visible light signals are transmitted to the reception device. The wavelength of visible light 1 emitted by the LD is generally within a range of 380 nm to 830 nm. In the optical modulation element for an optical communication system, since optical elements 101, 102, and 103 functioning as LN modulators are used, a visible light signal can be obtained by LD current modulation and LN voltage modulation on the basis of an electric signal received from the electric signal generation element 6013. When a visible light signal 2 is generated, only one of the LD current modulation and the LN voltage modulation may be used.

The optical elements 101, 102, and 103 are Mach-Zehnder-type optical modulators. When a visible light signal is generated with only the LN voltage modulation, the time required for modulation of the visible light 1 into bright light or dark light using the Mach-Zehnder-type optical modulators is shorter than the on/off switching time of the visible light source. If the optical element with a laser diode is used inside the optical communication system, the generation speed of a visible light signal increases.

In this manner, miniaturization of the optical communication system can be realized using an optical communication system which uses the optical element according to the present disclosure.

### Embodiment of Smart Glasses

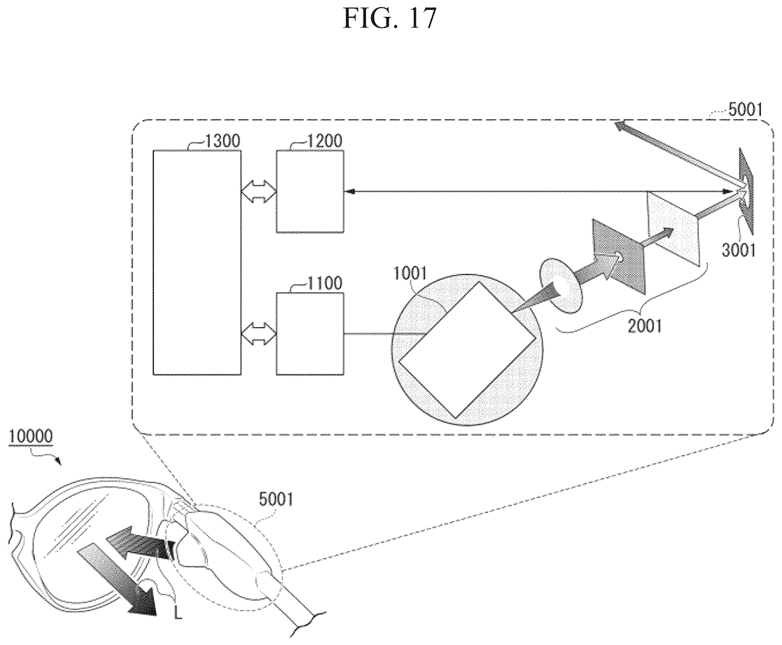

Next, smart glasses using an optical engine including the optical element according to the present disclosure will be described. Smart glasses, represented by augmented reality (AR) glasses and virtual reality (VR) glasses are expected to become a small-sized wearable device. In such a device, optical elements emitting full color visible light are used as key elements for depicting high-quality images. FIG. 17 shows an explanatory conceptual diagram of an optical engine 5001 according to the present embodiment. The diagram illustrates a state in which a frame 10010 of eyeglasses 10000 is equipped with the optical engine 5001. The reference sign L indicates image display light.

The optical engine 5001 has a light source unit 1001 and an optical scanning mirror 3001. The light source unit according to the embodiment described above is used as the light source unit 1001 included in the optical engine 5001.

Regarding the light source unit 1001, a light source unit having the built-in optical element 201 with a laser diode including a red laser 41r, a green laser 41g, and a blue laser 41b can be used. Laser light emitted from the light source unit 1001 attached to the eyeglass frame is reflected by the optical scanning mirror and enters the human eye so that an image (video image) is directly projected onto the retina.

In addition, regarding the light source unit 1001, a module having a built-in optical element with a laser diode to which LN optical waveguides for a near infrared light laser and near infrared light or a Si waveguide for near infrared light and multiplex portions for near infrared light and visible light are further added can be used. In this constitution, an image is directly projected onto the retina while eye tracking is performed.

For example, the optical scanning mirror 3001 is an MEMS mirror. In order to project a 2D image, it is preferable to adopt a two-axis MEMS mirror which vibrates so as to reflect laser light by changing the angle in the horizontal direction (X direction) and the vertical direction (Y direction).

The optical engine 5001 has a collimator lens, a slit, and an ND filter as an optical system 2001 for optically processing laser light emitted from the light source unit 1001. This optical system 2001 is an example, and it may have a different constitution.

The optical engine 5001 has a laser driver 1100, an optical scanning mirror driver 1200, and a video controller 1300 for controlling these drivers.

In the optical engine 5001, since three wavelengths are multiplexed and output from the light source unit 1001, there is one optical component for each and it can be miniaturized, and since white light is produced through one beam spot, it is easier to increase the resolution.

In this manner, miniaturization of the smart glasses in their entirety can be realized using the optical engine including the optical element according to the present disclosure in smart glasses.

### Embodiment of Computer

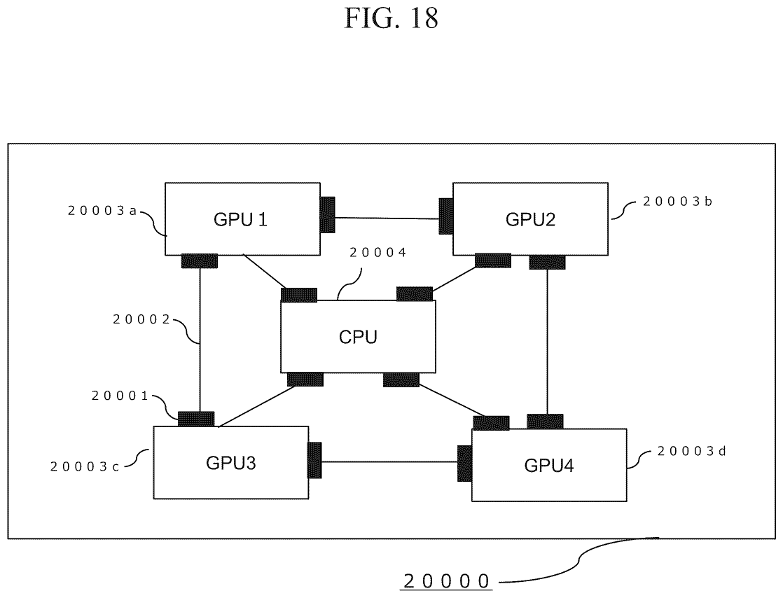

Next, regarding another application example, an embodiment of a computer using the optical element according to the present disclosure will be described. A computer 20000 shown in FIG. 18 includes photo-integrated circuits 20001 (hereinafter,

PICs) in which the optical element according to the present disclosure is used, optical wirings 20002, graphics processing units 20003 (hereinafter, GPUs), and a central processing unit (CPU) 20004.

The PICs 20001 are connected to the optical wiring 20002. The PICs 20001 are respectively provided in connection portions of GPUs 20003a, 20003b, 20003c, and 20003d, or the optical wirings of the CPU 20004. The GPU and the GPU or the GPU and the CPU are connected to each other via the PICs 20001 and the optical wirings respectively provided in the CPU or the connection portions of the GPUs.

In this manner, the optical computer 20000 can be realized using the PICs 20001 including the optical element according to the present disclosure. Optical elements in the related art had a large size, but it is now possible to transmit optical signals using optical elements in which miniaturization is realized, and it is possible to dramatically increase the performance of the computer. In addition, since miniaturization is realized with a single chip, it is now possible to mount it in a computer which could not be realized in the optical elements in the related art. Particularly, the computer of the present disclosure is suitable for computers used in fields such as generative AI, which require high-speed exchange of information between the GPU and the GPU and between the CPU and the GPU provided inside the computer.

An optical element according to the present disclosure is an optical element including a sapphire substrate having a first optical waveguide, and another substrate different from the sapphire substrate. The first optical waveguide is constituted of a lithium niobate film provided on one surface of the sapphire substrate. The first optical waveguide is disposed in a manner of being sandwiched between the substrate different from the sapphire substrate and the sapphire substrate.

In the optical element according to another aspect of the present disclosure, the sapphire substrate further has a first electrode. The first optical waveguide and the first electrode constitute a Mach-Zehnder-type optical modulator.

In the optical element according to another aspect of the present disclosure, the substrate different from the sapphire substrate is a silicon substrate. The silicon substrate has a second optical waveguide. The second optical waveguide is constituted of a polysilicon film or a silicon nitride film provided on the silicon substrate. The second optical waveguide is sandwiched between the sapphire substrate and the silicon substrate.

In the optical element according to another aspect of the present disclosure, the first optical waveguide and the second optical waveguide are optically connected.

The optical element according to another aspect of the present disclosure further includes a laser diode. The laser diode is connected to either the first optical waveguide or the second optical waveguide.

The optical element according to the present disclosure further has an electric circuit, and a second electrode connected to the electric circuit and applying a voltage to the Mach-Zehnder-type optical modulator via the first electrode. The electric circuit and the second electrode are sandwiched between another substrate different from the sapphire substrate and the sapphire substrate and operate as optical modulators.

In the optical element according to the present disclosure, visible light of 400nm to 800 nm propagates through the first optical waveguide.

In the optical element according to the present disclosure, near infrared light of 800 nm to 1600 nm propagates through the first optical waveguide.

In the optical element according to the present disclosure, the visible light has three wavelengths for red, green, and blue.

An optical communication system according to the present disclosure uses the optical element according to the present disclosure.

Smart glasses according to the present disclosure use the optical element according to the present disclosure.

A computer according to the present disclosure includes PICs including the optical element according to the present disclosure, optical wirings, a plurality of GPUs, and a CPU. The PIC is included in the GPUs and the CPU, and the plurality of GPUs are connected to each other and the GPUs and the CPU are connected to each other via the PICs and the optical wirings.

A method for manufacturing an optical element according to the present disclosure is a method for manufacturing an optical element constituted of a substrate different from a sapphire substrate and the sapphire substrate. The method has a first substrate patterning step of producing a first pattern on the substrate different from the sapphire substrate by patterning the substrate different from the sapphire substrate, a second substrate patterning step of producing a second pattern by forming a first optical waveguide on one surface of the sapphire substrate, a wafer bonding step of bonding one surface of the substrate different from the sapphire substrate having the first pattern formed in the first substrate patterning step and the one surface of the sapphire substrate having the second pattern formed in the second substrate patterning step, and a dicing step of dicing the substrate different from the sapphire substrate and the sapphire substrate integrated in the wafer bonding step.

According to another aspect of the present disclosure, in the method for manufacturing an optical element, the first substrate patterning step further includes forming a first through hole in the substrate different from the sapphire substrate, and filling the first through hole with metal.

According to another aspect of the present disclosure, in the method for manufacturing an optical element, the second substrate patterning step further includes forming a second through hole in the sapphire substrate, and filling the second through hole with metal.

According to another aspect of the present disclosure, in the method for manufacturing an optical element, the wafer bonding step is performed by a surface activated bonding method or an atomic diffusion bonding method.

According to another aspect of the present disclosure, in the method for manufacturing an optical element, adhesion is performed using a resin in the wafer bonding step.

Hereinabove, regarding a substrate different from a sapphire substrate constituting an optical element, a silicon substrate has been described as an example. However, other substrates such as a GaAs substrate or an InP substrate can also be applied.

### EXPLANATION OF REFERENCES

11 Silicon substrate (substrate different from sapphire substrate)
12 Core layer
12a Optical waveguide on silicon substrate side (Si optical waveguide)
13 Cladding layer on silicon substrate side (Si cladding layer)
14a Through electrode on silicon substrate side (Si through electrode)
14b Signal electrode on silicon substrate side (Si signal electrode)
14c Grounding electrode on silicon substrate side (Si grounding electrode)
15a CMOS circuit including transistor (electric circuit)
21 Sapphire substrate
22 Lithium niobate thin film (LN thin film)
23 Cladding layer on LN side (LN cladding layer)
24 Mach-Zehnder-type optical waveguide (MZI optical waveguide)
24a LN ridge portion (optical input/output portion)

What is claimed is:

1. An optical element comprising:
a sapphire substrate having a first optical waveguide; and
a substrate different from the sapphire substrate,
wherein the first optical waveguide is constituted of a lithium niobate film provided on one surface of the sapphire substrate, and
the first optical waveguide is disposed in a manner of being sandwiched between the substrate different from the sapphire substrate and the sapphire substrate.

2. The optical element according to claim 1,
wherein the sapphire substrate further has a first electrode, and
the first optical waveguide and the first electrode constitute a Mach-Zehnder-type optical modulator.

3. The optical element according to claim 1,
wherein the substrate different from the sapphire substrate is a silicon substrate,
the silicon substrate has a second optical waveguide,
the second optical waveguide is constituted of a polysilicon film or a silicon nitride film provided on the silicon substrate, and
the second optical waveguide is sandwiched between the sapphire substrate and the silicon substrate.

4. The optical element according to claim 3,
wherein the first optical waveguide and the second optical waveguide are optically connected.

5. The optical element according to claim 1 further comprising:
a laser diode,
wherein the laser diode is connected to either the first optical waveguide or the second optical waveguide.

6. The optical element according to claim 2 further comprising:
a laser diode,
wherein the laser diode is connected to either the first optical waveguide or the second optical waveguide.

7. The optical element according to claim 3 further comprising:
a laser diode,
wherein the laser diode is connected to either the first optical waveguide or the second optical waveguide.

8. The optical element according to claim 4 further comprising:
a laser diode,
wherein the laser diode is connected to either the first optical waveguide or the second optical waveguide.

9. The optical element according to claim 2 further comprising:
an electric circuit; and
a second electrode connected to the electric circuit and applying a voltage to the Mach-Zehnder-type optical modulator via the first electrode,
wherein the electric circuit and the second electrode are sandwiched between the substrate different from the sapphire substrate and the sapphire substrate and operate as optical modulators.

10. The optical element according to claim 5,
wherein visible light of 400 nm to 800 nm propagates through the first optical waveguide.

11. The optical element according to claim 5,
wherein near infrared light of 800 nm to 1600 nm propagates through the first optical waveguide.

12. The optical element according to claim 10,
wherein the visible light has three wavelengths for red, green, and blue.

13. An optical communication system using the optical element according to claim 11.

14. Smart glasses using the optical element according to claim 12.

15. A computer comprising:
PICs including the optical element according to claim 9;
optical wirings;
a plurality of GPUs; and
a CPU,
wherein the PIC is included in the GPUs and the CPU, and the plurality of GPUs are connected to each other and the GPUs and the CPU are connected to each other via the PICs and the optical wirings.

16. A method for manufacturing an optical element constituted of a substrate different from a sapphire substrate and the sapphire substrate, the method comprising:
a first substrate patterning step of producing a first pattern on the substrate different from the sapphire substrate by patterning the substrate different from the sapphire substrate;
a second substrate patterning step of producing a second pattern by forming a first optical waveguide on one surface of the sapphire substrate;
a wafer bonding step of bonding one surface of the substrate different from the sapphire substrate having the first pattern formed in the first substrate patterning step and the one surface of the sapphire substrate having the second pattern formed in the second substrate patterning step; and
a dicing step of dicing the substrate different from the sapphire substrate and the sapphire substrate integrated in the wafer bonding step.

17. The method for manufacturing an optical element according to claim 16,
wherein the first substrate patterning step further includes
forming a first through hole in the substrate different from the sapphire substrate, and
filling the first through hole with metal.

18. The method for manufacturing an optical element according to claim 16,
wherein the second substrate patterning step further includes
forming a second through hole in the sapphire substrate, and
filling the second through hole with metal.

19. The method for manufacturing an optical element according to claim 16,
wherein the wafer bonding step is performed by a surface activated bonding method or an atomic diffusion bonding method.

20. The method for manufacturing an optical element according to claim 16,
wherein adhesion is performed using a resin in the wafer bonding step.
